(19) United States
(12) Patent Application Publication
(10) Pub. No.: US 2023/0207730 A1
(43) Pub. Date: Jun. 29, 2023

(54) SEMICONDUCTOR HETEROSTRUCTURE

(71) Applicant: UNIVERSITY COLLEGE CORK - NATIONAL UNIVERSITY OF IRELAND, CORK, Cork (IE)

(72) Inventors: Vitaly Z. ZUBIALEVICH, Cork (IE); Peter J. PARBROOK, Carrigaline, Co. Cork (IE); Pietro PAMPILI, Carrigaline, Co. Cork (IE)

(21) Appl. No.: 17/926,119

(22) PCT Filed: May 18, 2021
(86) PCT No.: PCT/EP2021/063210

§ 371 Date: Nov. 17, 2022

(30) Foreign Application Priority Data
May 18, 2020 (EP) 2007350.8

(51) Int. Cl. H01L 33/24; H01L 33/06; H01L 33/18; H01L 33/32; H01L 33/44

(52) U.S. Cl. CPC H01L 33/24; H01L 33/06; H01L 33/18; H01L 33/32; H01L 33/44

(57) ABSTRACT

A semiconductor heterostructure device for use as a component in an optoelectronic component, the device has a substrate, a nanocolumn extending from the substrate, a self-centred passivation layer on top of the nanocolumn, an active region which comprises a quantum well (QW) stack on a vertical side of the nanocolumn and wherein the passivation layer extends horizontally outwards from the nanocolumn to overhang the nanocolumn and the QW stack. The device provides for efficient NC heterostructure based light emitting diodes (LEDs) and other optoelectronic devices with an active region located purely on non-polar facets of the NCs. It also eliminates parasitic current paths allowing core-shell nanorod-based LEDs with emission from the desired facets only.

### FIELD

The disclosure relates to a semiconductor heterostructure and a method of making the same. In particular the disclosure relates to a nanocolumn (NC) heterostructure suitable for use as an optoelectronic device such as a light emitting diode (LED), or any other semiconductor device based on quantum wells such as a resonant-tunnelling diode.

### BACKGROUND TO THE INVENTION

Nanocolumn based LEDs may comprise nanowires, nanorods or nanopillars. The LED is a device composed of an array of NCs where the active region is vertically stacked and sandwiched between n- and p-type regions of the NC body. They can be either grown by a bottom-up method, for example by molecular beam epitaxy or fabricated from the top down.

Such NCs with an axially arranged active region exhibit improved crystalline quality despite being grown on non-native substrates. However, the active region area of such a device is reduced in comparison to a flat analogue and no emission from non-polar planes of NCs can be generated for c-plane samples.

Alternatively, in core-shell type NCs the active region is placed all around the NC body. They are better quality and allow for an improvement in the total active region area well above that in an analogous flat structure. This is achieved by using high filling factors of NC arrays and high aspect ratios of NCs themselves. Most of the active region areas correspond to nonpolar m-planes, where a built-in electric field is absent. The absence of a quantum confinement Stark effect associated with the built-in electric fields leads to improved radiative recombination rates, which can lead to improved light output efficiency and also be crucial for certain high frequency applications.

Core-shell NCs typically have both semi-polar and non-polar facets (sometimes also top c-plane facets too). As the growth rate on the slanted semi-polar facets is normally slower in comparison to both non-polar and polar facets, the stack of quantum wells and barriers (QW stack) is thinner there leading to a parasitic pathway for electron-hole recombination.

In most cases, this issue is left unaddressed so that the non-polar facets get partially by-passed and the total active region area cannot be utilised fully. Moreover, as different facets incorporate indium differently during InGaN shell growth, they have different peak emission wavelengths. The resulting emission spectrum is composed of different bands with their relative intensities generally depending on excitation level applied.

When NCs are over-grown to form GaN—InGaN core-shell heterostructures, even initially flat topped NCs convert into apex topped ones with much thinner QW stacks on the slant semi-polar facets and often a thick quantum dot or disk at or near the pyramid apex. FIGS. 1a and 1b show prior art devices. In FIG. 1a, the device 1 comprises a wafer 3, III-nitride nanocolumns 5, which are overgrown to form QW stack 7 and cladding layers 8 around them which have slanted semi-polar facets 9 and horizontal polar facets 11 in addition to the vertical non-polar facets 12.

FIG. 1b shows a device 13 which comprises a wafer 15, III-nitride nanocolumns 17 which are overgrown to form QW stack 19 and cladding layers 14. FIG. 1b shows slanted semi-polar facets 21 and vertical non-polar facets 22. The QWs in the stack 19, 21 have very different thicknesses (and compositions) on different facets (including the potential for quantum dots 24 at the pyramid apex), which means that they emit light at different wavelengths, which is undesirable.

III-nitride nanocolumns 5, 17 are overgrown to form a target QW stack around them 7, 19. Typically, this leads to the formation also of slanted (semi-polar 9, 21), and horizontal (polar 11) facets or quantum dots (24) in addition to the target vertical (non-polar) ones 7, 19. Both the semi-polar and polar facets lead to the creation of parasitic current paths with either non-radiative or undesired radiative (wrong wavelength) recombination. Thus, significant current by-passes the non-polar side walls.

One of possible solutions to this problem is to grow the final part of GaN core undoped. This part however needs to be quite thick because of possible unintentional doping. From the active region area point of view this part of NC is lost as no current can be injected to the portion of the QW stack on sidewalls of this undoped GaN.

In another solution which is the closest prior art, (D. W. Lin et al Purely sidewall InGaN/GaN core-shell nanorod green light-emitting diodes, 2015 International Conference on Optical MEMS and Nanophotonics (OMN), pp. 1-2 and A.-J. Tzou et al High-Efficiency InGaN/GaN Core-Shell Nanorod Light-Emitting Diodes With Low-Peak Blueshift and Efficiency Droop, IEEE Trans. Nanotechnol., 16 (2017) 355-358), a cap is used to cover the body of the dry etched NC. When such NCs are overgrown to form core-shell heterostructure, semi-polar facets are formed outside the cap layer and so the by-passing problem is solved only partly: no current flows through the c-plane facet but current can still flow through the semi-polar facets. Moreover, this method does not address the problem of built-in dislocations.

Other problems in the field are the so-called green gap problem i.e. the lack of an efficient emitter in the green and another problem is efficiency droop i.e. decrease of the internal (and as a result external) quantum efficiency at high carrier densities. These problems are particularly pronounced for display Applications where a high colour purity is required. For example, U.S. Pat. Publication No. US2014/0246647 A1 disclose a process that includes a mechanical removal of all the unwanted facets at nanorod apexes and the relative quantum-well regions previously deposited on them followed by passivation of the resulting nanorod top facet with an insulator placed using a separate lithographic step. The same polishing-off approach was also proposed in an earlier Pat. Publication No. US 2008/0036038 A1, for the purpose of obtaining flat mirrors of a nanowire laser device. However, this process is very difficult to achieve industrial implementation, as the precise height control (on a sub-micrometre scale) of the polishing step is hardly possible across a full wafer of large diameters (20 and 30 cm are current industry standards in the field). In addition to that, both processes rely on a bottom-up approach, whereby the nanostructures are grown on a previously patterned substrate, a technique that is known to lead to inhomogeneous heights and also significant variations in diameter between nanorods.

There is therefore a need to provide a semiconductor heterostructure device and a method of making the same to overcome at least one of the above mentioned problems.

### SUMMARY

In accordance with a first aspect of the invention there is provided, as set out in the appended claims, a semiconductor heterostructure device for use as a component in an optoelectronic device, the device comprising:
a substrate;
a nanocolumn extending from the substrate;
a passivation layer on top of the nanocolumn;
an active region which comprises a quantum well (QW) stack on a vertical side of the nanocolumn; and wherein the passivation layer comprises a self-centred passivation disc like shape positioned to extend horizontally outwards from the nanocolumn to overhang the nanocolumn and the QW stack.

The present invention provides a new type of structure and based on an industrially compatible top-down approach, whereby quantum wells on nanocolumn facets of unwanted orientations are eliminated. An important aspect to the invention is the presence of a novel, self-centred passivation disc, or disc like shape, created on top of the nanostructures before the deposition of the quantum wells. In addition to preventing the current injection directly into the nanocolumn, the structure has a completely new function of acting as a three-dimensional constraint for the epitaxial growth of the quantum wells, forcing the quantum wells to be deposited only along the target facets. The self-centring system for the dielectric caps means that, unlike the previously disclosed processes, this invention does not rely on any lithographic alignment step. This enables significantly higher nanostructure densities to be achieved.

In one embodiment, the overhang is formed by etching the nanocolumn to reduce the width of the nanocolumn and to reduce the number of dislocations.

In one embodiment, the etching comprises wet etching.

In one embodiment, the overhang is between 0.05 and 1.5 microns.

In one embodiment, a second passivation layer is deposited on the substrate between adjacent nanocolumns.

In one embodiment, the nanocolumns with the passivation layer are annealed and/or overgrown in an ammonia containing atmosphere to controllably form m-plane facets and/or remove some residual dislocations prior to deposition of the QW stack.

In one embodiment, the device further comprises a top contact layer, for example a p-doped contact layer.

In one embodiment, the top contact layer is grown upwards from the substrate.

In one embodiment, a metal contact is deposited on the top contact layer.

In one embodiment, the top contact layer extends a predetermined distance up the nanocolumn.

In one embodiment, the nanocolumn further comprises residual slanted facets and the predetermined distance is set such that the top contact layer is not operatively coupled to the slanted facets.

In one embodiment, the quantum well(s) are located on non-polar facets of the nanocolumn.

In one embodiment, the passivation layer comprises an insulating dielectric material.

In one embodiment, the passivation layer comprises SiO₂.

In one embodiment, the passivation layer comprises SiNₓ.

In one embodiment, the passivation layer comprises a combination of insulating dielectric materials.

In one embodiment, the passivation layer has a thickness of between 50 and 150 nanometres.

In one embodiment, the passivation layer is created by sputtering.

In one embodiment, the passivation layer is created using plasma enhanced chemical vapour deposition (PECVD).

In one embodiment, the passivation layer is created using atomic layer deposition (ALD).

In one embodiment, the thickness of the passivation layer can be selected to make the structure more reflective

In one embodiment, the distance from a metal layer can be tuned to make the structure more reflective.

In one embodiment, the thickness of the passivation layer can be selected to maximise interference for reflection to assist with extraction of light through the back of the device.

In one embodiment, the nanocolumn comprises a III-nitride compound.

In one embodiment, the nanocolumn comprises n-type Gallium Nitride.

In one embodiment, the nanocolumn comprises n-type Aluminium Gallium Nitride.

In one embodiment, the nanocolumn comprises n-type Aluminium Nitride.

In one embodiment, the nanocolumn is formed by dry etching which reduces the number of dislocations.

In one embodiment, the nanocolumn is formed by lithography.

In one embodiment, the passivation layer is formed using a mask located above the passivation layer and configured to prevent the removal of portions of the passivation layer.

In one embodiment, the mask is a hard mask.

In one embodiment, the mask comprises self-assembled nanospheres possibly shrunk by wet or dry etch to control their diameter.

In accordance with a second aspect of the invention there is provided a semiconductor heterostructure device for use as a component in an optoelectronic device, the device comprising:
a substrate;
a nanocolumn extending from the substrate;
a passivation layer on top of the nanocolumn;
an active region which comprises a QW stack on a vertical side of the nanocolumn; and wherein the passivation layer extends horizontally outwards from the nanocolumn to overhang the nanocolumn and the QW stack and wherein the nanocolumn further comprises residual slanted facets and the top contact layer extends a predetermined distance up the nanocolumn such that the top contact layer is not operatively coupled to the slanted facets.

In one embodiment, the quantum well(s) are located on non-polar facets of the nanocolumn.

In one embodiment, a metal contact is provided on top of the contact layer.

In one embodiment, hole injection is provided through the metal contact around the nanocolumn.

It will be appreciated that the features of the first aspect of the invention which relate to the substrate, nanocolumn, passivation layer and active region may be incorporated in the device of the second aspect of the invention.

In accordance with a third aspect of the invention there is provided a method for creating a semiconductor heterostructure device for use as a component in an optoelectronic device, the method comprising the steps of:
applying a passivation layer to a semiconductor wafer;
selectively applying a mask to the passivation layer;
processing the semiconductor wafer to create nanocolumns in the positions defined by the mask;
removing a portion of the nanocolumn located under the passivation layer such that the passivation layer overhangs the nanocolumn.

In one embodiment, the overhang is formed by etching the nanocolumn to reduce the number of dislocations.

In one embodiment, the etching comprises wet etching.

In one embodiment, the overhang is between 0.05 and 1.5 microns.

In one embodiment, a second passivation layer is deposited on the substrate between adjacent nanocolumns.

In one embodiment, the nanocolumns with the passivation layer are annealed and/or overgrown in an ammonia containing atmosphere to controllably form m-plane facets and/or remove some residual dislocations prior to deposition of the QW stack.

In one embodiment, the method further comprises the step of depositing a top contact layer over the passivation layer, nanocolumn and QW stack.

In one embodiment, the top contact layer is grown upwards from the substrate.

In one embodiment, a metal contact is deposited on the top contact layer.

In one embodiment, the top contact layer extends a predetermined distance up the nanocolumn.

In one embodiment, the nanocolumn further comprises residual slanted facets and the predetermined distance is set such that the top contact layer is not operatively coupled to the slanted facets.

In one embodiment, the QW stack is located on non-polar facets of the nanocolumn.

In one embodiment, the passivation layer comprises an insulating dielectric material.

In one embodiment, the passivation layer comprises SiO₂.

In one embodiment, the passivation layer comprises SiNₓ.

In one embodiment, the passivation layer comprises a combination of insulating dielectric materials.

In one embodiment, the passivation layer has a thickness of between 50 and 150 nanometres.

In one embodiment, the passivation layer is created by sputtering.

In one embodiment, the passivation layer is created using plasma enhanced chemical vapour deposition (PECVD).

In one embodiment, the passivation layer is created using atomic layer deposition (ALD).

In one embodiment, the thickness of the passivation layer can be selected to make the structure more reflective

In one embodiment, the distance from a metal contact can be tuned to make the structure more reflective.

In one embodiment, the thickness of the passivation layer can be selected to maximise interference for reflection to assist with extraction of light through the back of the device.

In one embodiment, the nanocolumn is formed by dry etching.

In one embodiment, the nanocolumn is formed by lithography.

In one embodiment, the passivation layer is formed using a mask located above the passivation layer and configured to prevent the removal of portions of the passivation layer.

In one embodiment, the mask is a hard mask.

In one embodiment, wherein the mask comprises self-assembled nanospheres possibly shrunk by wet or dry etch to control their diameter.

In one embodiment, the passivation layer forces the overgrowth of the QW stack to happen only along the intended direction. In one embodiment, the passivation layer inhibits any undesirable current injection through the top of the nanocolumns.

It is expected that the heterostructures so created will result in the production of more efficient optoelectronic devices, particularly more efficient LEDs with improved spectral purity.

In accordance with a fourth aspect of the invention there is provided a method for creating a semiconductor heterostructure device for use as a component in an optoelectronic device, the method comprising the steps of:
applying a passivation layer to a semiconductor wafer;
selectively applying a mask to the passivation layer;
processing the semiconductor wafer to create nanocolumns in the positions defined by the mask;
removing a portion of the nanocolumn located under the passivation layer such that the passivation layer overhangs the nanocolumn
wherein the nanocolumn further comprises residual slanted facets and a top contact layer is added which extends a predetermined distance up the nanocolumn such that the top contact layer is not operatively coupled to the slanted facets.

In one embodiment, the quantum well(s) are located on non-polar facets of the nanocolumn.

In one embodiment, a metal contact is provided on top of the contact layer.

In one embodiment, hole injection is provided through a metal contact around the nanocolumn.

It will be appreciated that the method steps of the method of the third aspect of the invention which relate to the substrate, nanocolumn, passivation layer and active region may be incorporated in the device of the second aspect of the invention.

### BRIEF DESCRIPTION OF THE DRAWINGS

The invention will be more clearly understood from the following description of an embodiment thereof, given by way of example only, with reference to the accompanying drawings, in which:

FIGS. 1a and 1b are schematic diagrams which show heterostructures which besides the desired non-polar facets have polar and semi-polar regions;

FIG. 2 is a schematic diagram which shows an embodiment of a heterostructure in accordance with the present invention;

FIG. 3 is a schematic diagram which shows a first step in an example of a method of making a heterostructure in accordance with the present invention;

FIGS. 4a and 4b are schematic diagrams which show a second step in an example of a method of making a heterostructure in accordance with the present invention;

FIGS. 5a and 5b are schematic diagrams which show an alternative second step to that of FIGS. 4a and 4b in an example of a method of making a heterostructure in accordance with the present invention;

FIGS. 6a and 6b are schematic diagrams which show the step of creating the overhanging region of the passivation layer;

FIG. 7 is a schematic diagram which shows a step in an example of a method of making a heterostructure in accordance with the present invention in which a passivation layer is added between the columns;

FIG. 8 is a schematic diagram which shows a step in an example of a method of making a heterostructure in accordance with the present invention in which the active region is grown;

FIG. 9 is a schematic diagram which shows a step in an example of a method of making a heterostructure in accordance with the present invention in which a top contact layer (for example p-type layer) is grown;

FIG. 10 is a schematic diagram which shows a step in an example of a method of making a heterostructure in accordance with the present invention in which metal contacts are deposited on the structure;

FIG. 11 is a schematic diagram which shows a heterostructure with a semi-polar part;

FIG. 12 is a schematic diagram which shows potential short circuiting in a heterostructure of FIG. 11;

FIG. 13 is a schematic diagram of a novel heterostructure in accordance with the invention which solves the problem of short circuiting;

FIG. 14 is a schematic diagram of a novel heterostructure in accordance with the present invention, with a core-shell topology; and

FIG. 15 is a schematic diagram of a novel heterostructure in accordance with the present invention, with a core-shell topology.

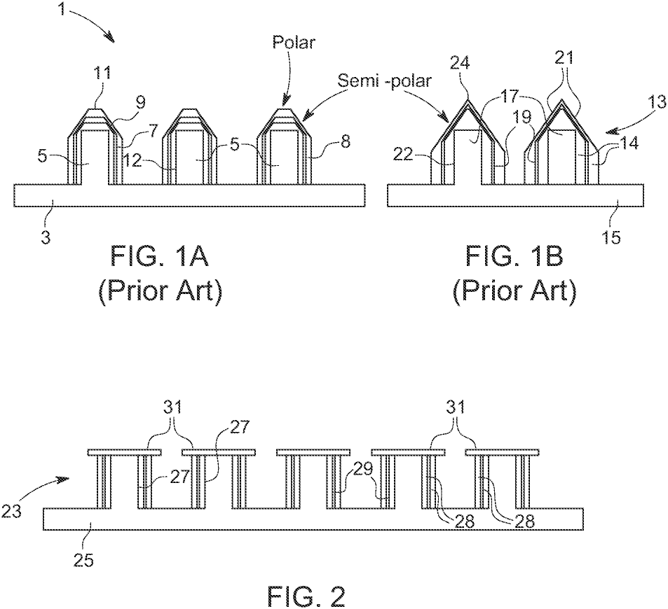

### DETAILED DESCRIPTION OF THE DRAWINGS

In at least one embodiment, the present invention provides a hybrid top-down-regrowth technique to fabricate dense arrays of GaN nanocolumns that are capped with a protective layer covering their top c-plane facets.

The present invention provides for efficient NC heterostructure based light emitting diodes (LEDs) and other optoelectronic devices with an active region located purely on non-polar facets of the NCs.

In this and other examples, the material used was of typical crystalline quality (dislocation density of 10⁸-10⁹ cm⁻³). In this and other examples of the present invention dislocation reduction is achieved by removal of almost all initial material and the associated dislocations by
i. a dry inductively coupled plasma (ICP) to form NCs and by
ii. a wet etch to shrink them laterally underneath the dielectric masking overhanging “umbrella” or passivation layer.

Thus, the narrow NCs are left capped with a pre-deposited thin layer of material to which QW material does not stick at typical growth conditions (any material that can be used as a mask in selective area growth approaches).

The present invention eliminates parasitic current paths allowing LEDs to be created with emissions from the desired facets only. In one example the QW material is InGaN and the LED is a core-shell nanorod-based LED.

In one example, the hard nanomask comprised an array of closely packed silica nanospheres. However other techniques such as e-beam lithography, nanoimprinting can be used.

The automatic self-alignment to each NC nanodisk allows regrowth of the NCs recovering their diameter without formation of new dislocations while keeping constant NC height across the whole array and suppressing the formation of slant semi-polar facets and apexes at NC tops.

Moreover, the same persists when the capped NCs are overgrown to form a core-shell structure so that the shell can be formed only or mostly on their non-polar facets.

After the dry etch has been applied to form initial NCs, the layer remains only where it was shadowed by a hard nanomask.

FIG. 2 is a schematic diagram which shows an embodiment of a heterostructure in accordance with the present invention. FIG. 2 shows a device 23 which comprises a wafer 25 and five nanocolumns 27 which extend vertically from the wafer 25. InGaN QW stack 29 and cladding layers 28 are grown on the vertical walls of the nanocolumn 27 and the horizontal top surface has a cap or passivation layer which is a thin layer of material that prevents InGaN epitaxial growth, therefore the passivation layer prevents growth of a QW stack on the horizontal capped surface. The passivation layer effectively comprises a self-centred passivation disc like shape positioned on top of each nanocolumn.

The present invention exploits the presence of a specially processed, self-aligned, passivation layer which, in this embodiment comprises insulating self-centred passivation disks, to force the overgrowth of the QW stack only along the intended direction. In addition to that, the disks inhibit any undesirable current injection through the top of the nanocolumns. The heterostructures created results in the production of more efficient optoelectronic devices, particularly more efficient LEDs with improved spectral purity. The position of the self-centred passivation disc like shape functions as a constraint to ensure the quantum well stack is deposited along the vertical side of the column resulting in improved optoelectronic devices and material properties.

In one or more embodiments of the present invention, the NC is annealed in addition to bringing it up to the appropriate temperature for the QW stack overgrowth. This would assist both in the preforming shaping of the rods for the QW stack growth to the m-facets and also may ensure that any dislocations that can be remove are removed.

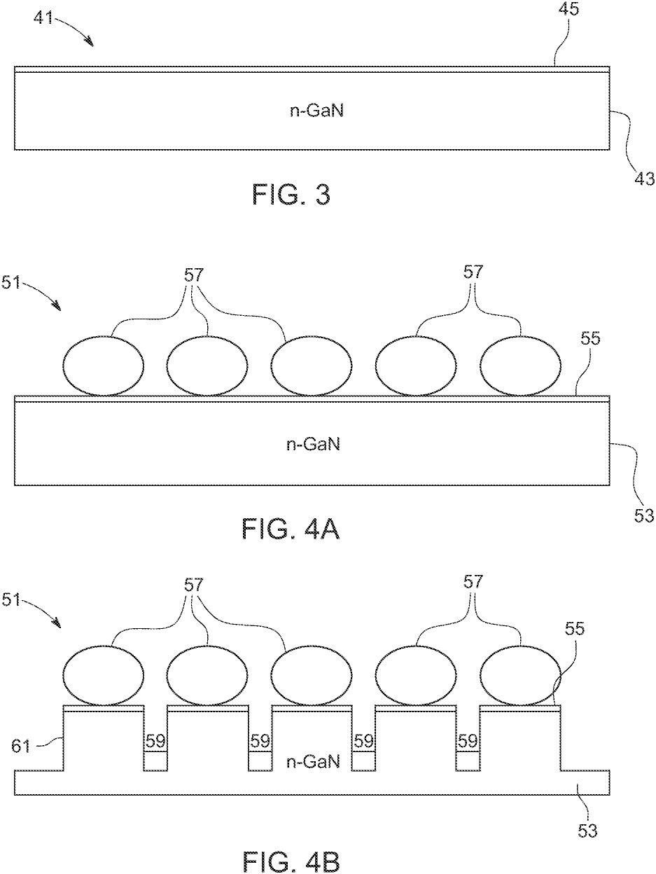

FIG. 3 is a schematic diagram 41 which shows a first step in an example of a method of making a heterostructure in accordance with the present invention. The III-nitride semiconductor wafer (typically n-doped GaN or AlGaN) 43 is preliminary covered with an insulating layer (e.g. SiO₂ or SiNₓ) 45. This passivation layer 45 has a typical thickness of 50-150 nm, and can be deposited by sputtering, PECVD, or by any other thin film deposition technique.

FIGS. 4a and 4b are schematic diagrams 51 which shows the formation of nanocolumns 61 in a second step in an example of a method of making a heterostructure in accordance with the present invention. The figures show an n-type GaN wafer 53 with the passivation layer 55 positioned below a hard mask, which in this example comprises self-assembled nanospheres 57, subsequently shrunk to control initial NC diameter.

As shown in FIG. 4b, nanocolumns 61 are formed with spaces 59 between the columns by means of a top down dry-etch process.

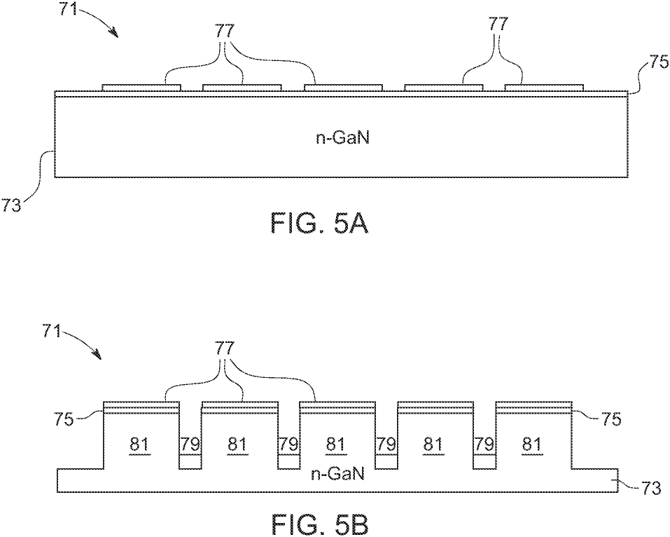

FIGS. 5a and 5b are schematic diagrams which shows an alternative second step 71 to that of FIGS. 4a and 4b in an example of a method of making a heterostructure in accordance with the present invention.

FIGS. 5a and 5b show a metal hard mask 77 which is patterned by standard optical lithography, nano-imprint, or Talbot lithography. The mask 77 is positioned on top of the passivation layer 75 and the wafer 73. The choice of the lithographic technique depends on the dimensions of the nanocolumns, which can vary from approximately one hundred nanometres up to a few microns, and the uniformity requirements. FIG. 5b shows the formation of nanocolumns 81 separated by spaces 79.

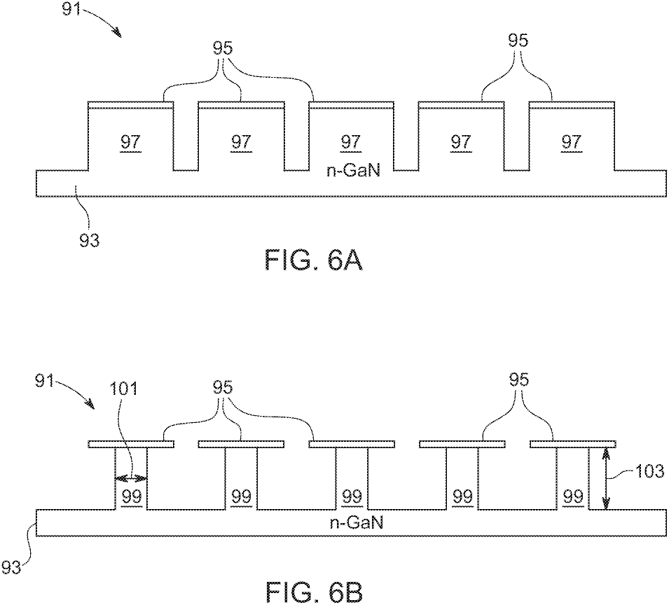

FIGS. 6a and 6b are schematic diagrams 91 which show the step of creating the overhanging region of the passivation layer.

The overhanging regions are formed by a wet-etch step for a few hours in solutions that contain hydroxide, which are able to anisotropically etch III-nitride materials. In particular, KOH-based solutions can be used for this purpose such as for example the resist developer AZ400K. The combined use of anisotropic etch and passivation layers that cannot be etched by the solution has never been reported before and constitutes a novel feature of the method of the present invention that makes it possible the formation of the overhangs created in the present invention.

As shown, in FIGS. 6a and 6b, at the start of the etching process, the structure comprises columns 97 with vertical side walls positioned below the passivation layer 95 on top of a substrate 93. The etching process removes material from the columns 99 to create an overhang of the passivation layer 95 and shrinks the NCs to their final diameter 101. In this example, the width 101 may be between 0.05 and 1.5 microns, while height 103 may be between 0.3 and 10 microns.

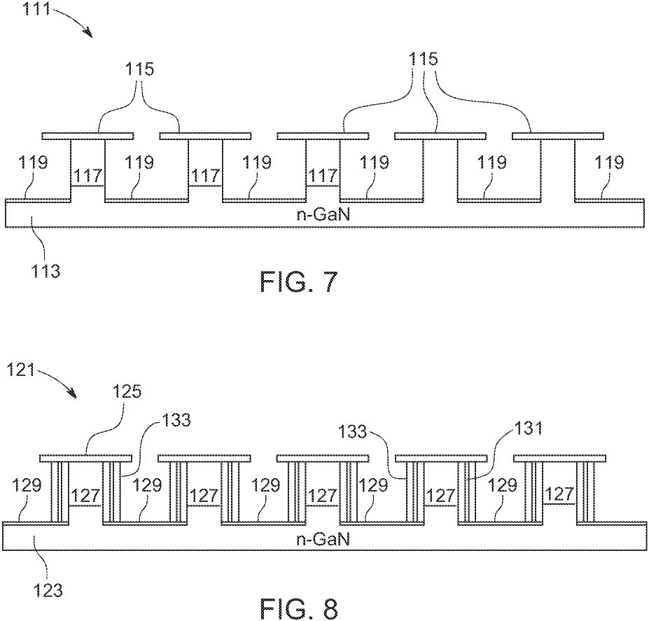

FIG. 7 is a schematic diagram 111 which shows a step in an example of a method of making a heterostructure in accordance with the present invention in which a passivation layer is added between the columns. The figure shows a wafer 113, passivation layer 115, an etched nanocolumn 117 and additional passivation layer 119.

The passivation layer 119 is deposited on the area between the bases of the nanocolumns. Any suitable deposition technique can be used, provided the floor is covered and, at the same time, the sidewalls are essentially exposed. This also includes spin-coating and curing of liquid passivation materials (such as HSQ or spin-on-glass), possibly followed by a diluted wet etch to remove any residuals from the sidewalls.

FIG. 8 is a schematic diagram 121 which shows a step in an example of a method of making a heterostructure in accordance with the present invention in which the active region is grown. It shows a wafer 123, passivation layer 125, an etched nanocolumn 127, second passivation layer 129; and a QW stack 131 and cladding layers 133 that have been subsequently created in a regrowth step.

The presence of the passivation layers forces the growth of QW stack and cladding layers to take place only at the nanocolumn sidewalls. By controlling the growth conditions, the nanocolumn cross-section can be transformed from circular into hexagonal so that the QW stack can be precisely oriented on the non-polar m-plane facets.

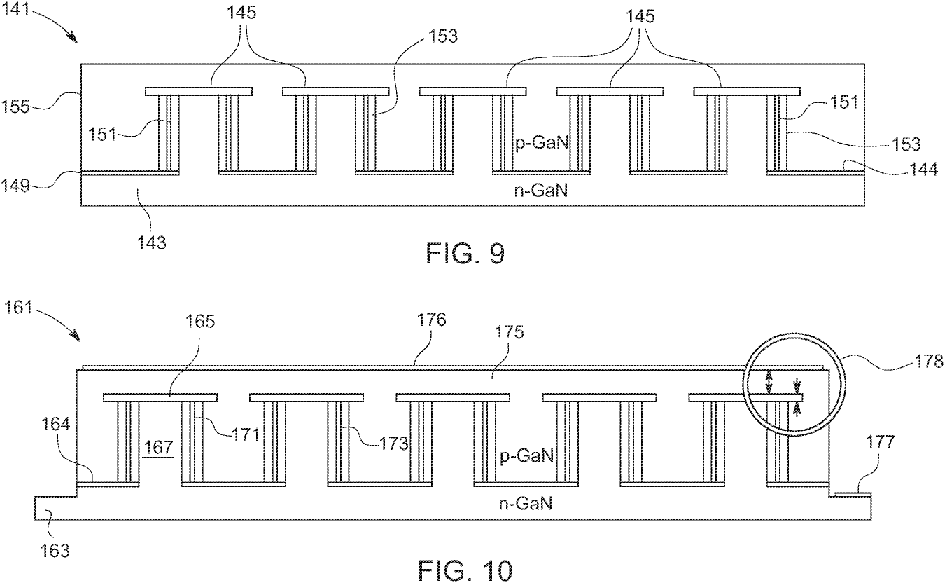

FIG. 9 is a schematic diagram 141 which shows a step in an example of a method of making a heterostructure in accordance with the present invention in which a top contact layer is grown. It shows a wafer 143 with a passivation layer 145, an etched nanocolumn 147 a second passivation layer 149 a QW stack 151, cladding layers 153 and a top contact layer 155.

This final layer 155 forms the top contact of the LED device and will typically be p-type, in contrast to the n-type doping of the starting material and nanocolumn cores. However, for other quantum-well based electronic devices such as resonant-tunnelling diodes, it can also be n-type.

By suppressing the doping on the first 50-200 nm of this in-filling material, a virtually insulating thin layer can be created at the base of the device, which can be used in substitution of the second passivation layer 149 at the nanocolumn floor (previously deposited, as shown in FIG. 7, second passivation layer 119).

FIG. 10 is a schematic diagram 161 which shows a step in an example of a method of making a heterostructure in accordance with the present invention in which contacts are deposited on the structure. FIG. 10 shows wafer 163 with a passivation layer 165, an etched nanocolumn 167 a second passivation layer 169 a QW stack 171, cladding layers 173 and a top contact layer 175, an anode metal layer 176 and a cathode metal layer 177.

The devices are subsequently fabricated as standard planar LEDs. In particular, mesa etch, and anode- and cathode-contact metal deposition are performed.

“Vertical” LED topologies are equally viable, as technology concept has no impact on these design aspects. To improve the light extraction from the bottom side, the thickness of the umbrella top-passivation and its distance from the metal can be tuned to make the structure more reflective 178.

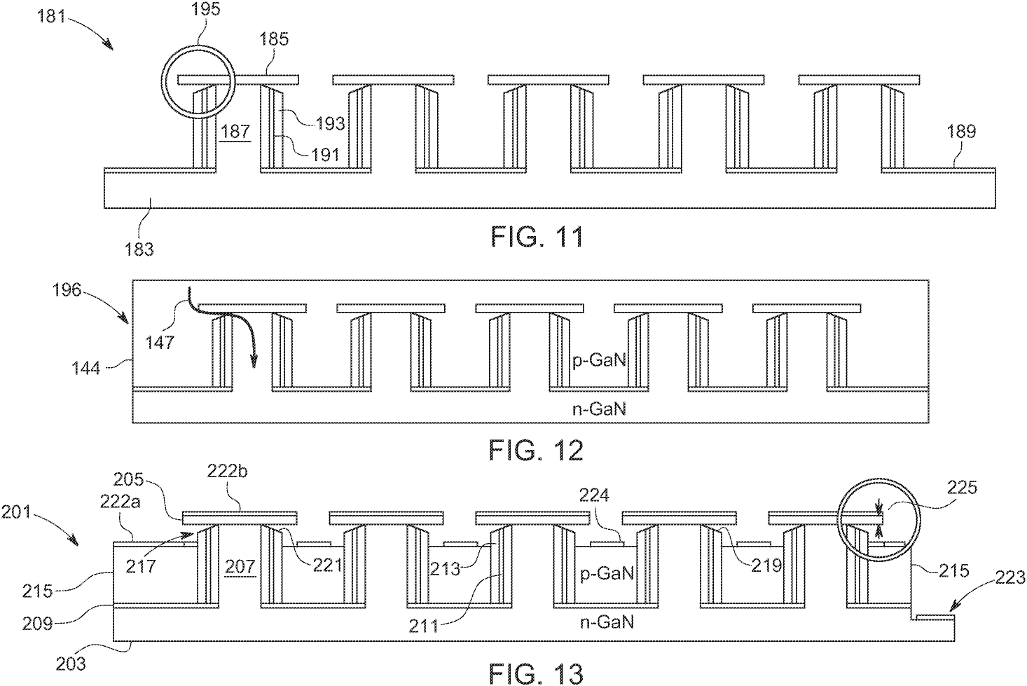

In addition to fully suppressing the formation of horizontal polar facets on top of the nanocolumns, the nano-umbrellas are also able to suppress the slanted semi-polar facets. Depending on the growth conditions, this semipolar suppression may not be 100% achieved. FIG. 11 is a schematic diagram 181 which shows a heterostructure with a small semi-polar part which comprises residual slanted facets formed below the insulating disks. FIG. 11 shows a wafer 183 a passivation layer or cap 185 an etched column 187 a second passivation layer 189 between the vertical sections of the column, a QW stack 191 with cladding layers 193. The area highlighted in circle 195 contains a residual semi-polar facet.

FIG. 12 is a schematic diagram 196 which has the features of FIG. 11 but shows top contact 199 and the short circuit pathway of the injection current 197 via the semi-polar facet.

FIG. 13 is a schematic diagram 201 of an alternative embodiment of this novel heterostructure which solves the problem of short circuiting. It shows a wafer 203, a passivation layer 205, an etched column 207 a second passivation layer on the wafer between the columns 209 a QW stack 211 and claddings 213. The top contact layer 215 is grown to a height which is below the level of the residual semi-polar facet 217 and has a metal contact 222 on its top surface. The anode metal contact 222 is only active on contact layer 215 (marked 222a) and is inactive when on the passivation layer 205 (marked 222b) In this example, the top contact material 215 is grown from the bottom floor upwards which makes it possible to control its thickness and stop its growth just before the full height of the overhang of the passivation layer 205 is reached. Finally, a cathode metal contact to n-GaN is deposited 223.

With this configuration the device may be fabricated using a standard, planar-LED process, but the modified version of the contact metallization 222 will prevent the current from being injected in the areas around the slanted facets. In fact, the overhang will shadow the critical parts during the metal evaporation and create small holes 224 in the metal contact 222 around each nanocolumn. This alternative fabrication process is able to completely inhibit any current shortcut through the slanted facets. Further, in this configuration the top contact metal can be chosen to be reflective.

Design of the thickness 225 of passivation layer 205 can be chosen to maximise light extraction through the bottom of the device. The thickness of the passivation layer may also be designed to maximised interference for reflection to assist with extraction of light through the back of the device.

This may be applied in both the device design where the passivation layer is overgrown by the top contact layer (effectively encapsulating the passivation layer) and in the design where the passivation layer is not overgrown (the semi polar facet issue solution variation). In the case where the device design is the overgrowth then the thickness of the contact layer between the metal contact and the passivation layer is also engineerable to maximise reflection.

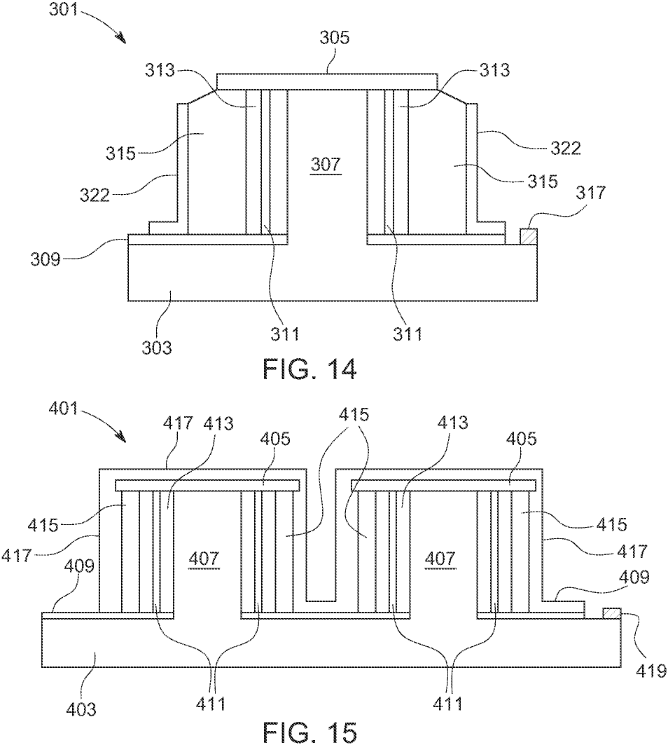

FIG. 14 is a schematic diagram 301 of a novel heterostructure with a core-shell topology. It shows a wafer 303, a passivation layer 305, an etched column 307 a second passivation later 309 on the wafer. A QW stack 311, claddings 313, anode metal contact 322 and cathode metal contact 317 are also shown. The p-type contact layer 315 is grown not to infill between the columns but left isolated.

FIG. 15 is a schematic diagram 401 of a novel heterostructure with a core-shell topology. It shows a wafer 403, with two heterostructures with passivation layers 405, etched columns 407, second passivation layers 409 on the wafer between the columns. QW stack 411, claddings 413, anode metal contact 417 and cathode metal contact 419 are also shown. The p-type contact layer 415 is grown not to infill between the columns but is left isolated.

In the examples of FIGS. 14 and 15, the thickness of the passivation layers (305, 405) can be designed for extraction. In this case ensuring the metal surrounding the nanocolumn contact is reflective. This is readily achievable in the visible InGaN QWs described above.

In one or more embodiment of the present invention, the pitch of the NC array and the array geometry can (at the smaller length scales) be engineered to produce photonic crystal effects which could improve the extraction efficiency of the device.

In the specification, the terms “up”, vertical and horizontal have their ordinary meaning and refer to positions and directions relative to the substrate.

In the specification the terms “comprise, comprises, comprised and comprising” or any variation thereof and the terms “include, includes, included and including” or any variation thereof are considered to be totally interchangeable and they should all be afforded the widest possible interpretation and vice versa.

The invention is not limited to the embodiments hereinbefore described but may be varied in both construction and detail.

1. A semiconductor heterostructure device for use as a component in an optoelectronic device, the device comprising:
a substrate;
a nanocolumn extending from the substrate;
a passivation layer on top of the nanocolumn;
an active region which comprises a quantum well stack on a vertical side of the nanocolumn; and wherein the passivation layer comprises a self-centred passivation disc like shape positioned to extend horizontally outwards from the nanocolumn to overhang the nanocolumn and the quantum well stack.

2. The device of claim 1 wherein the overhang is formed by etching the nanocolumn to reduce the width of the nanocolumn and to reduce the number of dislocations.

3. The device of claim 1 or claim 2 wherein the position of the self-centred passivation disc like shape functions as a constraint to ensure the quantum well stack is deposited along the vertical side of the column..

4. The device as claimed in any preceding claim wherein a second passivation layer is deposited on the substrate between adjacent nanocolumns.

5. The device as claimed any preceding claim wherein the nanocolumns with the passivation layer are annealed with an ammonia containing atmosphere to controllably form m-plane facets and/or remove some residual dislocations prior to deposition of the quantum well shell stack.

6. The device as claimed in any preceding claim which further comprises a top contact layer.

7. The device as claimed in claim 6 wherein, the top contact layer is configured to be electrically insulating at or near the bottom of the nanocolumn and acts as a passivation layer between the columns.

8. The device as claimed in claim 6 wherein the top contact layer is a p-type contact layer grown upwards from the substrate and optionally the top p-type contact layer is obtained by expanding the nanocolumns until they merge and coalesce.

9. The device as claimed in claim 6 to 8 wherein a metal contact is deposited on the top contact layer.

10. The device as claimed in claims 6 to 9 wherein the top contact layer extends a predetermined distance up the nanocolumn.

11. The device as claimed in claims 8 wherein the nanocolumn further comprises residual slanted facets and the predetermined distance is set such that the top contact layer is not operatively coupled to the slanted facets.

12. The device as claimed in any preceding claim wherein the quantum well stack is located on non-polar facets of the nanocolumn.

13. The device as claimed in any preceding claim wherein the passivation layer comprises an insulating dielectric material.

14. The device as claimed in any preceding claim wherein the passivation layer comprises SiO₂.

15. The device as claimed in claims 1 to 13 wherein the passivation layer comprises SiNₓ.

16. The device as claimed in any preceding claim wherein the passivation layer has a thickness of between 50 and 150 nanometres.

17. The device as claimed in any preceding claim wherein the passivation layer is created by sputtering.

18. The device as claimed in claims 1 to 16 wherein the passivation layer is created using plasma enhanced chemical vapour deposition (PECVD).

19. The device as claimed in claims 1 to 16 wherein the passivation layer is created using atomic layer deposition (ALD).

20. The device as claimed in any preceding claim wherein the thickness of the passivation layer can be selected to make the structure more reflective.

21. The device as claimed in any preceding claim wherein the distance from the passivation layer to a metal contact can be tuned to make the structure more reflective.

22. The device as claimed in any preceding claim wherein the thickness of the passivation layer can be selected to maximise interference for reflection to assist with extraction of light through the back of the device.

23. The device as claimed in any preceding claim wherein the nanocolumn comprises a III-nitride compound.

24. The device as claimed in any preceding claim wherein the nanocolumn comprises n-type Gallium Nitride.

25. The device as claimed in claims 1 to 23 wherein the nanocolumn comprises n-type Aluminium Gallium Nitride.

25. The device as claimed in claims 1 to 23 wherein the nanocolumn comprises n-type Aluminium Nitride.

26. The device as claimed in any preceding claim wherein the nanocolumn is formed by dry etching which reduces the number of dislocations.

27. The device as claimed in claims 1 to 25 wherein the nanocolumn is formed by lithography.

28. The device as claimed in any preceding claim wherein the passivation layer is formed using a mask located above the passivation layer and configured to prevent the removal of portions of the passivation layer.

29. The device as claimed in claim 28 wherein the mask is a hard mask.

30. The device as claimed in claim 28, wherein the mask comprises self-assembled nanospheres, and optionally shrunk by wet or dry etch to control their diameter.

31. The device as claimed in any preceding claim wherein the passivation layer forces the overgrowth of the quantum well stack to happen only along the intended direction.

32. The device as claimed in any preceding claim wherein, the passivation layer inhibits any undesirable current injection through the top of the nanocolumns.

33. A semiconductor heterostructure device for use as a component in an optoelectronic device, the device comprising:
a substrate;
a nanocolumn extending from the substrate;
a passivation layer on top of the nanocolumn;
an active region which comprises a quantum well QW stack on a vertical side of the nanocolumn; and wherein the passivation layer extends horizontally outwards from the nanocolumn to overhang the nanocolumn and the QW stack and wherein the
nanocolumn further comprises residual slanted facets and the top contact layer extends a predetermined distance up the nanocolumn such that the top contact layer is not operatively coupled to the slanted facets.

34. The device as claimed in any preceding claim wherein the quantum well stack is located on non-polar facets of the nanocolumn.

35. The device as claimed in claims 33 and 34 wherein a metal contact is provided on top of the contact layer.

36. The device as claimed in claim 35 wherein hole injection is provided through the metal contact around the nanocolumn.

37. A method for creating a semiconductor heterostructure device for use as a component in an optoelectronic device, the method comprising the steps of:
applying a passivation layer to a semiconductor wafer;
selectively applying a mask to the passivation layer;
processing the semiconductor wafer to create nanocolumns in the positions defined by the mask;
removing a portion of the nanocolumn located under the passivation layer such that the passivation layer overhangs the nanocolumn to form a self-centred passivation disc like shape; and
depositing a quantum well stack on a vertical side of the nanocolumn.

38. The method of claim 37 wherein the overhang is formed by etching the nanocolumn and to reduce the number of dislocations.

39. The method as claimed in claim 37 or claim 38 wherein the etching comprises wet etching.

40. The method of claim 37 or claim 38 wherein the passivation disc like shape functions as a constraint to ensure the quantum well stack is deposited only along the vertical side of the column.

41. The method as claimed in claims 37 to 40 wherein a second passivation layer is deposited on the substrate between adjacent nanocolumns.

42. The method as claimed in claims 37 to 41 wherein the nanocolumns with the passivation layer are annealed and/or overgrown in an ammonia containing atmosphere to controllably form m-plane facets and/or remove some residual dislocations prior to deposition of the quantum well shell stack.

43. The method as claimed in claims 37 to 42 which further comprises the step of depositing a top contact layer over the passivation layer, nanocolumn and quantum well stack.

44. The method as claimed in claim 43 wherein the top contact layer is grown upwards from the substrate.

45. The method as claimed in claims 43 or 44 wherein a metal contact is deposited on the top contact layer.

46. The method as claimed in claims 43 to 45 wherein the top contact layer extends a predetermined distance up the nanocolumn.

47. The method as claimed in claims 37 to 46 wherein the passivation layer comprises an insulating dielectric material.

48. The method as claimed in claim 45 wherein the nanocolumn further comprises residual slanted facets and the predetermined distance is set such that the top contact layer is not operatively coupled to the slanted facets.

49. The method as claimed in claims 37 to 48 wherein, the quantum well stack is located on non-polar facets of the nanocolumn.

50. The method as claimed in claims 37 to 49 wherein the passivation layer comprises SiO₂.

51. The method as claimed in claims 37 to 50 wherein, the passivation layer comprises SiNₓ.

52. The method as claimed in claims 37 to 51 wherein the passivation layer has a thickness of between 50 and 150 nanometres.

53. The method as claimed in claims 37 to 52 wherein the passivation layer is created by sputtering.

54. The method as claimed in claims 37 to 53 wherein the passivation layer is created using plasma enhanced chemical vapour deposition (PECVD).

55. The method as claimed in claims 37 to 53 wherein the passivation layer is created using atomic layer deposition (ALD).

56. The method as claimed in claims 37 to 55 wherein, the thickness of the passivation layer can be selected to make the structure more reflective.

57. The method as claimed in claims 37 to 56 wherein, the distance from a metal contact can be tuned to make the structure more reflective.

58. The method as claimed in claims 37 to 57 wherein, the thickness of the passivation layer can be selected to maximise interference for reflection to assist with extraction of light through the back of the device.

59. The method as claimed in claims 37 to 58 wherein, the nanocolumn is formed by dry etching which reduces the number of dislocations.

60. The method as claimed in claims 37 to 59 wherein the nanocolumn is formed by lithography.

61. The method as claimed in claims 37 to 60 wherein the passivation layer is formed using a mask located above the passivation layer and configured to prevent the removal of portions of the passivation layer.

62. The method as claimed in claims 37 to 61 wherein the mask is a hard mask.

63. The method as claimed in claim 60, wherein the mask comprises self-assembled nanospheres, and optionally shrunk by wet or dry etch to control their diameter.

64. The method as claimed in claims 37 to 63 wherein, the passivation layer forces the overgrowth of the Quantum Well stack to happen only along the intended direction.

65. The method as claimed in claims 30 to 64 wherein, the passivation layer inhibits any undesirable current injection through the top of the nanocolumns.
